(19) United States
(12) Patent Application Publication
(10) Pub. No.: US 2026/0371609 A1
(43) Pub. Date: Nov. 19, 2026

(54) RRAM STRUCTURE AND FABRICATING METHOD OF THE SAME

(71) Applicant: UNITED MICROELECTRONICS CORP., Hsin-Chu City (TW)

(72) Inventor: ZHIBIAO ZHOU, Singapore (SG)

(73) Assignee: UNITED MICROELECTRONICS CORP., Hsin-Chu City (TW)

(21) Appl. No.: 19/227,522

(22) Filed: Jun. 4, 2025

(30) Foreign Application Priority Data
May 14, 2025 (CN) 202510615750.8

(51) Int. Cl. H10B 63/00

(52) U.S. Cl. CPC H10B 63/00

(57) ABSTRACT

An RRAM structure includes a first dielectric layer, a second dielectric layer covering the first dielectric layer, and an RRAM embedded in the first dielectric layer. The RRAM includes a bottom electrode, a resistive switching layer, and a top electrode stacked sequentially from bottom to top. A conductive element is embedded in the second dielectric layer, wherein the conductive element includes a conductive plug and a conductive pad. The conductive plug contacts the top electrode, and the conductive pad contacts the conductive plug and is positioned on the conductive plug. A first direction is defined as a direction from the top electrode toward the bottom electrode. When viewing along the first direction, the conductive plug is laterally offset from the center of the conductive pad.

### BACKGROUND OF THE INVENTION

### FIELD OF THE INVENTION

The present invention relates to a resistive random access memory (RRAM) structure and a method for fabricating the same, particularly to a method for fabricating a conductive element on an RRAM by using double exposure.

### DESCRIPTION OF THE PRIOR ART

With the increasing demand for storage density, speed, and low power consumption in modern electronic devices, conventional memory technologies such as dynamic random access memory (DRAM) and flash memory are gradually encountering performance and energy efficiency limitations. To address these challenges, resistive random access memory (RRAM), an emerging non-volatile memory technology, has attracted growing attention. RRAM stores data by changing the resistance state of materials, enabling data read and write operations through the application of voltage to alter the resistance of memory cells.

RRAM offers faster write speed, lower power consumption, and higher data endurance. Unlike traditional charge-based storage mechanisms, RRAM utilizes resistance change for data storage, which provides advantages such as a simple structure and strong process compatibility. Its non-volatile nature allows data to be retained even in the absence of power, making RRAM a promising candidate for applications in embedded systems, mobile devices, and high-performance computing.

### SUMMARY OF THE INVENTION

In view of the above, the present invention provides a method for forming a conductive element on an RRAM, in order to ensure that a top electrode of the RRAM reliably contacts the conductive element formed on it.

In one aspect, the disclosure relates to an RRAM structure including a first dielectric layer and a second dielectric layer disposed on the first dielectric layer. The RRAM is embedded within the first dielectric layer and includes a bottom electrode, a resistive switching layer, and a top electrode arranged in sequence from bottom to top. A conductive element is embedded within the second dielectric layer and includes a conductive plug electrically connected to the top electrode. A conductive pad is disposed on and in contact with the conductive plug. A first direction is defined from the top electrode toward the bottom electrode, and when viewed along the first direction, the conductive plug is laterally offset from the center of the conductive pad.

In another aspect, the disclosure relates to a fabricating method for an RRAM structure includes first providing a first dielectric layer, a second dielectric layer disposed on the first dielectric layer, and an RRAM embedded within the first dielectric layer. The RRAM includes a bottom electrode, a resistive switching layer, and a top electrode sequentially stacked from bottom to top. Then, a first mask layer and a second mask layer are formed to cover the second dielectric layer in sequence. After that, the second mask layer and the first mask layer are etched to define a conductive pad pattern therein. Subsequently, a third mask layer is formed to cover the second mask layer and fill the conductive pad pattern. Later, the third mask layer, the first mask layer, and the second dielectric layer are etched to form a conductive plug pattern within the conductive pad pattern. A first direction is defined from the top electrode toward the bottom electrode, and when viewed along this direction, the conductive plug pattern is laterally offset from a center of the conductive pad pattern. After forming the conductive plug pattern, the third mask layer is entirely removed. Next, using the remaining second mask layer and the first mask layer as an etch mask, the second dielectric layer is etched to form a conductive element trench, thereby exposing the top electrode through the trench. Finally, a metal layer is deposited to fill the conductive element trench, thereby forming a conductive element.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a fabricating method of an RRAM structure according to a first preferred embodiment of the present invention, wherein:

FIG. 2 depicts a stage following FIG. 1;

FIG. 3 depicts a stage following FIG. 2;

FIG. 4 depicts a stage following FIG. 3; and

FIG. 5 depicts a stage following FIG. 4.

FIGS. 6-8 illustrate a fabricating method of an RRAM structure according to a second preferred embodiment of the present invention, wherein:

FIG. 7 depicts a stage following FIG. 6; and

FIG. 8 depicts a stage following FIG. 7.

FIGS. 9-13 illustrate a fabricating method of an RRAM structure according to a third preferred embodiment of the present invention, wherein:

FIG. 10 depicts a stage following FIG. 9;

FIG. 11 depicts a stage following FIG. 10;

FIG. 12 depicts a stage following FIG. 11; and

FIG. 13 depicts a stage following FIG. 12.

FIGS. 14-16 illustrate a fabricating method of an RRAM structure according to a fourth preferred embodiment of the present invention, wherein:

FIG. 15 depicts a stage following FIG. 14; and

FIG. 16 depicts a stage following FIG. 15.

FIG. 17 depicts a top view of a conductive element and an RRAM structure according to the first through fourth preferred embodiments of the present invention.

### DETAILED DESCRIPTION

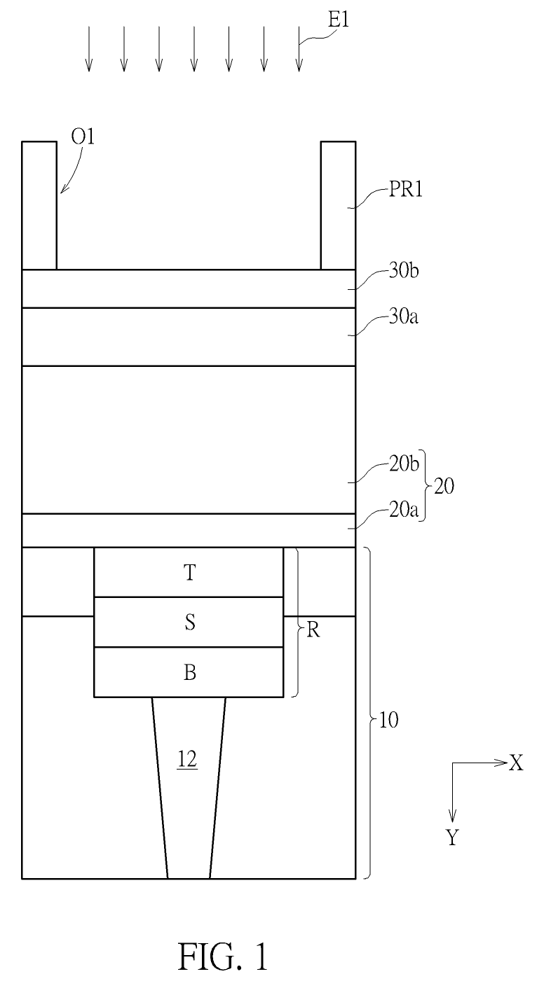

FIGS. 1-5 illustrate a fabricating method of an RRAM structure according to a first preferred embodiment of the present invention.

As shown in FIG. 1, a first dielectric layer 10 is provided. An RRAM R is embedded in the first dielectric layer 10. The RRAM R includes a bottom electrode B, a resistive switching layer S, and a top electrode T, sequentially stacked from bottom to top. A conductive plug 12 is embedded in the first dielectric layer 10 and is in contact with the bottom electrode B of the RRAM R. A second dielectric layer 20 covers the first dielectric layer 10. The second dielectric layer 20 may include multiple dielectric layers, such as dielectric layers 20a and 20b. Additionally, a first mask layer 30a, a second mask layer 30b, and a photoresist PR1 sequentially cover the second dielectric layer 20 from bottom to top. The first mask layer 30a and the second mask layer 30b may each include titanium nitride, silicon nitride, silicon oxide, or silicon oxynitride. According to a preferred embodiment of the present invention, the first mask layer 30a is titanium nitride, and the second mask layer 30b is silicon oxide. Then, A first exposure E1 of a double exposure process is performed to form an opening O1 in the photoresist PR1. The opening O1 defines a location for subsequently forming a conductive pad pattern. A second direction X is defined as being parallel to a top surface of the first dielectric layer 10. Along the second direction X, a width of the opening O1 is greater than a width of the top electrode T.

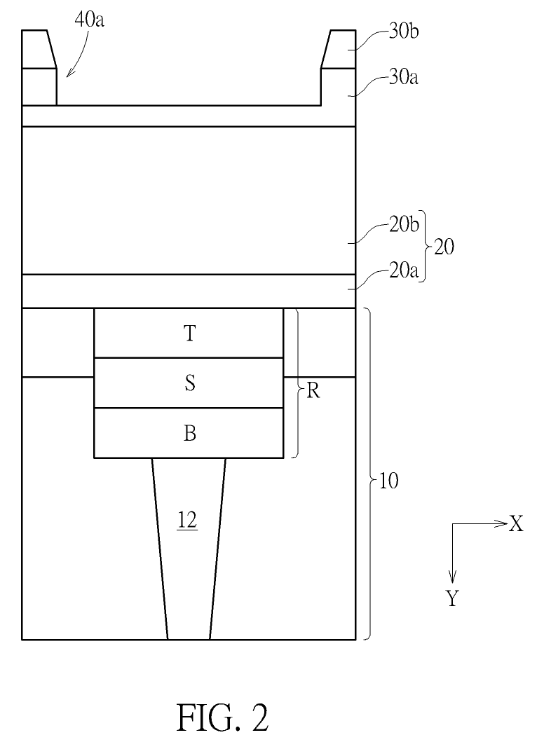

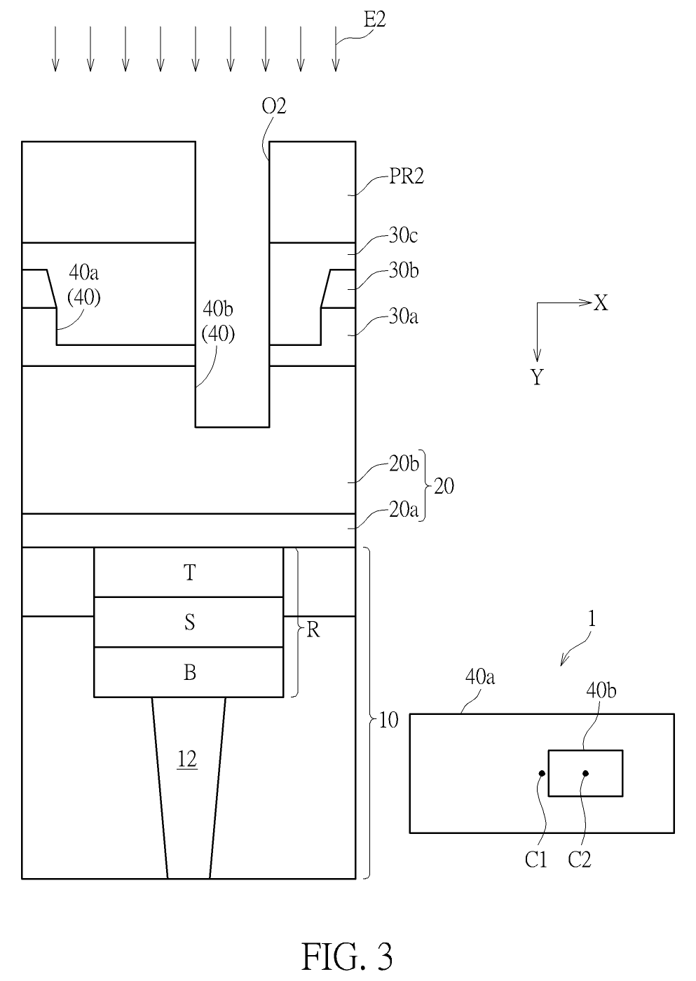

As shown in FIG. 2, the photoresist PR1 is used as a mask to etch the second mask layer 30b and the first mask layer 30a to form a conductive pad pattern 40a in the second mask layer 30b and the first mask layer 30a. Along the second direction X, a width of the conductive pad pattern 40a is greater than a width of the top electrode T. In addition, during the etching of the second mask layer 30b and the first mask layer 30a, the first mask layer 30a is not etched through. As shown in FIG. 3, the photoresist PR1 is first removed. Then, a third mask layer 30c is formed to cover the second mask layer 30b and fill the conductive pad pattern 40a. The third mask layer 30c is preferably a bottom anti-reflective coating (BARC). Subsequently, a photoresist PR2 is formed to cover the third mask layer 30c. Later, a second exposure E2 of the double exposure process is performed to form an opening O2 in the photoresist PR2. The opening O2 defines the position for subsequently forming a conductive plug pattern. After that, using the photoresist PR2 as a mask, the third mask layer 30c, the first mask layer 30a, and a dielectric layer 20b of the second dielectric layer 20 are etched to form a conductive plug pattern 40b in the conductive pad pattern 40a. A first direction Y is defined from the top electrode T toward the bottom electrode B. When viewed along the first direction Y, as shown in a top view 1, the conductive plug pattern 40b is laterally offset from a center C1 of the conductive pad pattern 40a. Specifically, a center C2 of the conductive plug pattern 40b is laterally offset from the center C1 of the conductive pad pattern 40a, but the conductive plug pattern 40b does not extend beyond the boundary of the conductive pad pattern 40a. An area of the conductive plug pattern 40b is smaller than that of the conductive pad pattern 40a. When the conductive pad pattern 40a is rectangular, the center C1 is defined as the intersection of the diagonals of the conductive pad pattern 40a. When the conductive plug pattern 40b is rectangular, the center C2 is defined as the intersection of the diagonals of the conductive plug pattern 40b. Additionally, when viewed from a sectional view, a width of the conductive plug pattern 40b is smaller than a width of the conductive pad pattern 40a. Therefore, during the etching of the third mask layer 30c, the first mask layer 30a, and the dielectric layer 20b of the second dielectric layer 20 to form the conductive plug pattern 40b, the second mask layer 30b is not etched. At this stage, the conductive plug pattern 40b is defined by the first mask layer 30a and the dielectric layer 20b of the second dielectric layer 20. Accordingly, the conductive plug pattern 40b is not present in the dielectric layer 20a. The conductive pad pattern 40a and the conductive plug pattern 40b together form a conductive element pattern 40.

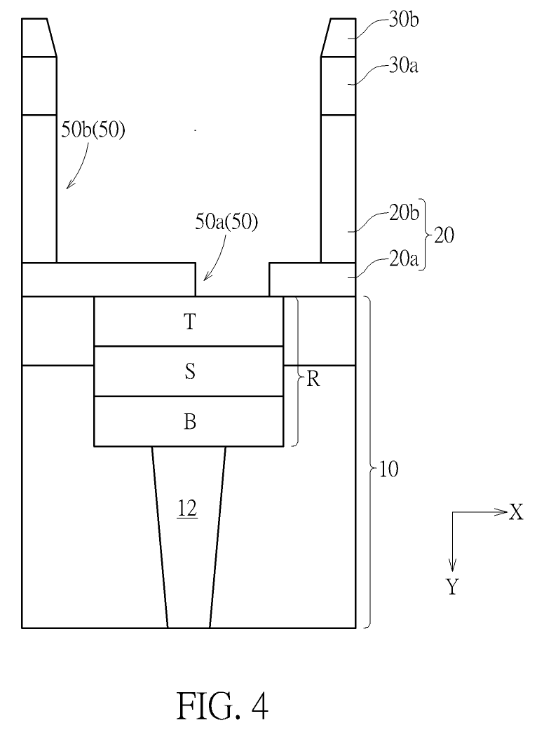

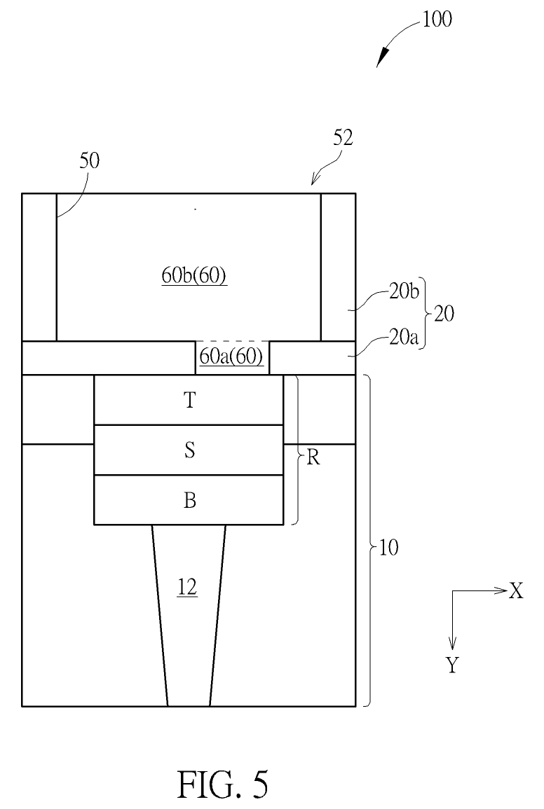

Please refer to FIGS. 3 and 4 simultaneously. The photoresist PR2 and the third mask layer 30c are completely removed. Subsequently, using the second mask layer 30b and the first mask layer 30a as a mask, and following the profile of the conductive element pattern 40, the first mask layer 30a and the second dielectric layer 20 (including the dielectric layers 20a and 20b) are etched to form a conductive element trench 50, and the top electrode T is exposed through the conductive element trench 50. Specifically, the conductive element trench 50 includes an upper trench 50b and a lower trench 50a. A width of the upper trench 50b is greater than a width of the lower trench 50a. The upper trench 50b is embedded only in the dielectric layer 20b, while the lower trench 50a is embedded only in the dielectric layer 20a. The top electrode T is exposed from the lower trench 50a. During the etching process, the second mask layer 30b and the first mask layer 30a may be completely removed. As shown in FIG. 5, a metal layer 52 is formed to fill the conductive element trench 50, thereby forming a conductive element 60. At this point, an RRAM structure 100 of the first preferred embodiment of the present invention is completed.

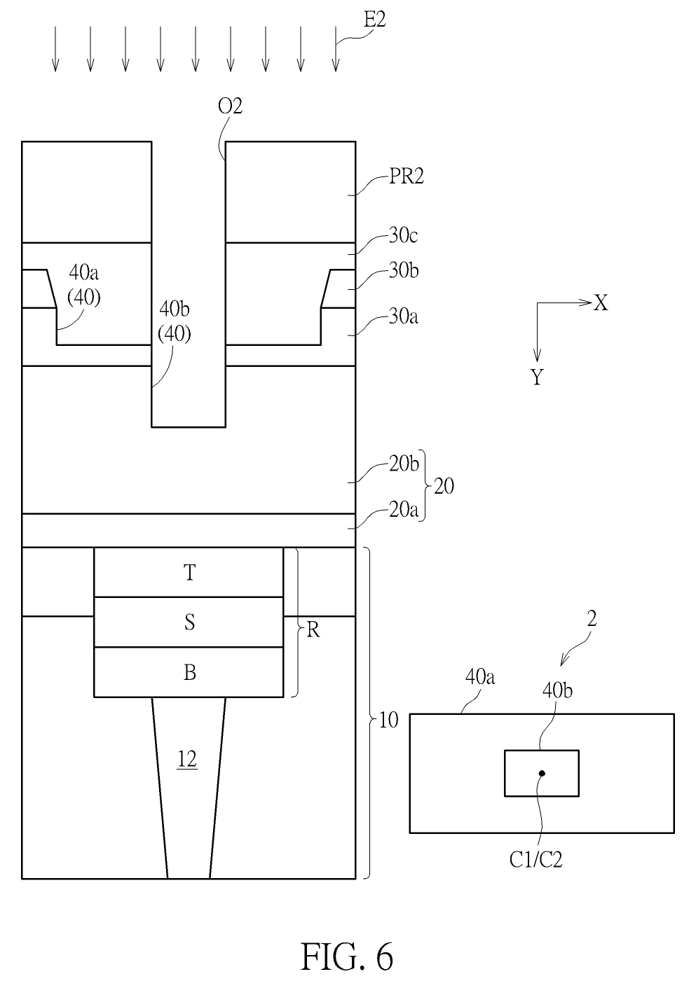

FIGS. 6-8 illustrate a fabricating method of an RRAM structure according to a second preferred embodiment of the present invention. Elements having the same functions and positions as those in the first preferred embodiment are designated by the same reference numerals.

The difference between the second preferred embodiment and the first preferred embodiment lies in that, in the second preferred embodiment, the conductive plug pattern 40b is located at the center C1 of the conductive pad pattern 40a. The center C2 of the conductive plug pattern 40b overlaps with the center C1 of the conductive pad pattern 40a. Other process steps are the same as those of the first preferred embodiment. Continuing from FIG. 2, as shown in FIG. 6, a third mask layer 30c is formed to cover the second mask layer 30b and fill the conductive pad pattern 40a. A photoresist PR2is then formed over the third mask layer 30c. An opening O2 is formed in the photoresist PR2. The opening O2 defines a location for subsequently forming a conductive plug pattern. Using the photoresist PR2 as a mask, the third mask layer 30c, the first mask layer 30a, and the dielectric layer 20b of the second dielectric layer 20 are etched to form a conductive plug pattern 40b in the conductive pad pattern 40a. When viewed along the first direction Y, as shown in a top view 2, the conductive plug pattern 40b is located at the center C1 of the conductive pad pattern 40a. In other words, the center C2 of the conductive plug pattern 40b overlaps with the center C1 of the conductive pad pattern 40a. The area of the conductive plug pattern 40b is smaller than that of the conductive pad pattern 40a. Additionally, when viewed from a sectional view, a width of the conductive plug pattern 40b is smaller than a width of the conductive pad pattern 40a. At this stage, the conductive pad pattern 40a and the conductive plug pattern 40b together form a conductive element pattern 40.

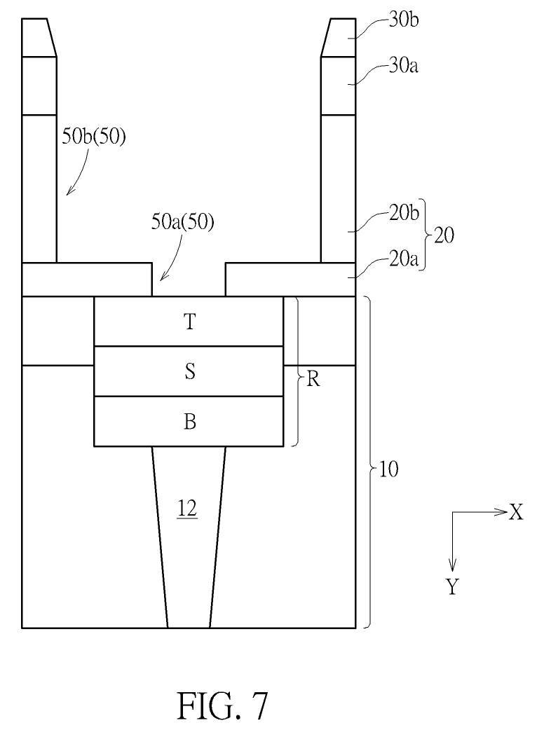

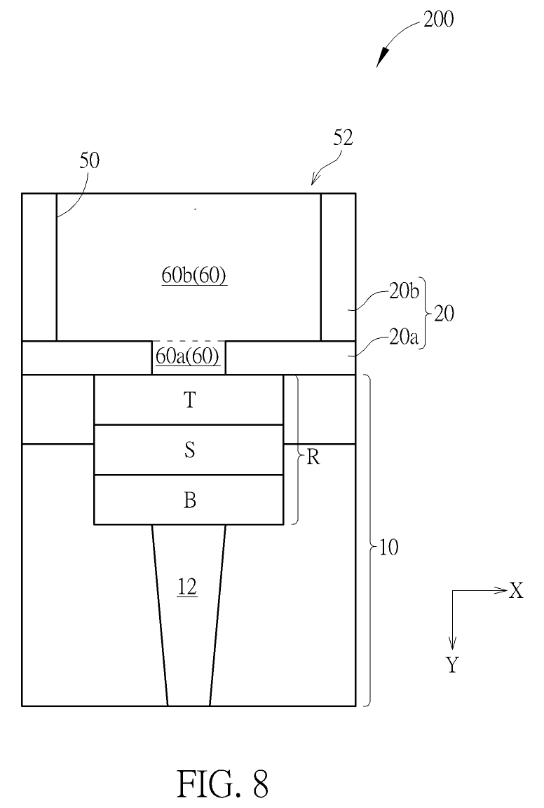

As shown in FIG. 7, the second mask layer 30b and the first mask layer 30a are used as a mask. Following the profile of the conductive element pattern 40, the first mask layer 30a and the second dielectric layer 20 are etched to form a conductive element trench 50, exposing the top electrode T through the conductive element trench 50. As shown in FIG. 8, a metal layer 52 is formed to fill the conductive element trench 50, thereby forming a conductive element 60. At this point, an RRAM structure 200 of the second preferred embodiment of the present invention is completed.

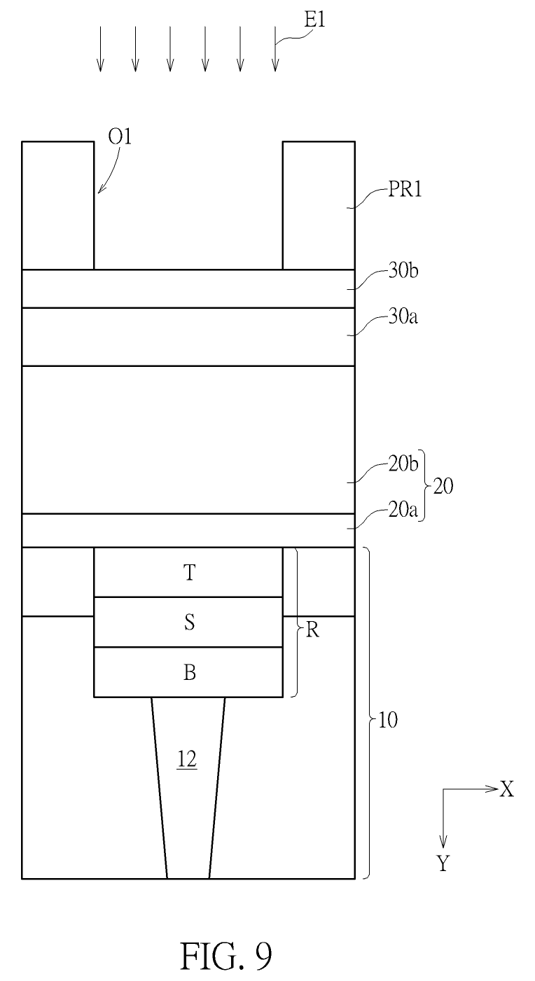

FIGS. 9-13 illustrate a fabricating method of an RRAM structure according to a third preferred embodiment of the present invention. Elements having the same functions and positions as those in the first preferred embodiment are designated by the same reference numerals.

As shown in FIG. 9, a first dielectric layer 10 is provided. An RRAM R is embedded in the first dielectric layer 10. The RRAM R includes a bottom electrode B, a resistive switching layer S, and a top electrode T sequentially stacked from bottom to top. A conductive plug 12 is embedded in the first dielectric layer 10 and contacts the bottom electrode B of the RRAM R. A second dielectric layer 20 covers the first dielectric layer 10. The second dielectric layer 20 may include multiple dielectric material layers, such as a dielectric layer 20a and a dielectric layer 20b. In addition, a first mask layer 30a, a second mask layer 30b, and a photoresist PR1 are sequentially formed to cover the second dielectric layer 20 from bottom to top. Later, a first exposure E1 of a double exposure process is then performed to form an opening O1 in the photoresist PR1. The opening O1 defines a location for forming a conductive pad pattern in a subsequent step. A second direction X is defined as a direction parallel to a top surface of the first dielectric layer 10. Along the second direction X, a width of the opening O1 is not greater than a width of the top electrode T. According to the preferred embodiment of the present invention, the width of the opening O1 is equal to the width of the top electrode T.

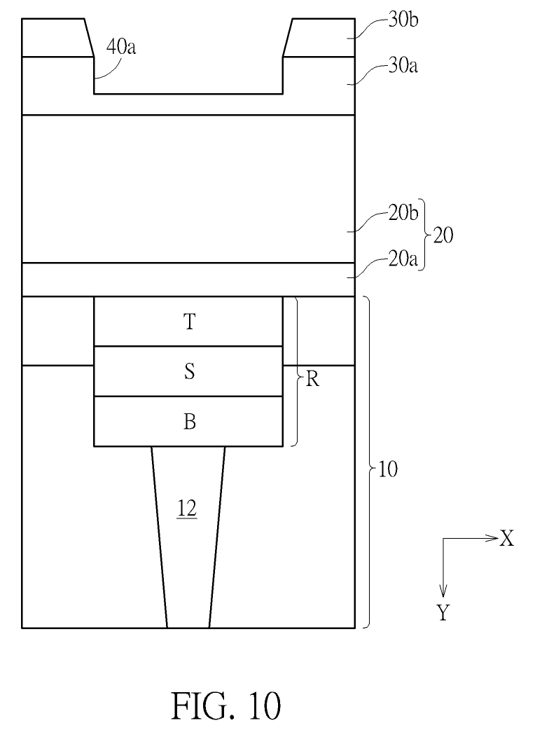

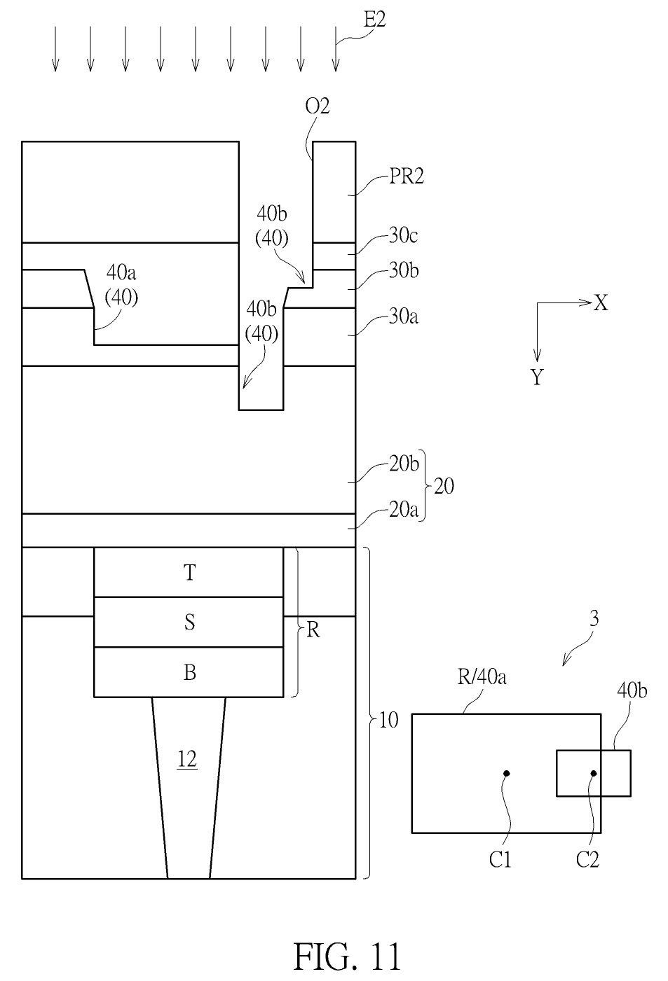

As shown in FIG. 10, using the photoresist PR1 as a mask, the second mask layer 30b and the first mask layer 30a are etched to form a conductive pad pattern 40a in the second mask layer 30b and the first mask layer 30a. Along the second direction X, the width of the conductive pad pattern 40a is not greater than the width of the top electrode T, and preferably, the width of the conductive pad pattern 40a is equal to the width of the top electrode T. In addition, during the etching of the second mask layer 30b and the first mask layer 30a, the first mask layer 30a is not etched through. As shown in FIG. 11, the photoresist PR1 is removed. Then, a third mask layer 30c is formed to cover the second mask layer 30b and fill the conductive pad pattern 40a. A photoresist PR2 is subsequently formed to cover the third mask layer 30c. Next, a second exposure E2 of the double exposure process is performed to form an opening O2 in the photoresist PR2, wherein the opening O2 defines a location for forming a conductive plug pattern in a subsequent step. Since the width of the conductive pad pattern 40a in the third preferred embodiment is smaller than the width of the conductive pad pattern 40a in the first preferred embodiment, the opening O2 may easily extend beyond the boundary of the conductive pad pattern 40a when the opening O2 is laterally offset from the center C1 of the conductive pad pattern 40a. In the third preferred embodiment, this condition occurs — that is, the opening O2 extends beyond the conductive pad pattern 40a.

A subsequent etching step is then performed, in which the photoresist PR2 is used as a mask to etch the third mask layer 30c, the second mask layer 30b, the first mask layer 30a, and the dielectric layer 20b of the second dielectric layer 20, so as to form a conductive plug pattern 40b within the conductive pad pattern 40a. A first direction Y is defined as a direction from the top electrode T toward the bottom electrode B. When viewed along the first direction Y, as shown in a top view 3, the conductive plug pattern 40b is laterally offset from a center C1 of the conductive pad pattern 40a. More specifically, a center C2 of the conductive plug pattern 40b is laterally offset from the center C1 of the conductive pad pattern 40a. Furthermore, the conductive plug pattern 40b extends beyond the boundary of the conductive pad pattern 40a. The area of the conductive plug pattern 40b is smaller than that of the conductive pad pattern 40a. In addition, when viewed in a sectional view, the width of the conductive plug pattern 40b is smaller than the width of the conductive pad pattern 40a. Moreover, because an etch rate of an etchant used in this etching step is lower for the second mask layer 30b and higher for the third mask layer 30c, the depth to which the opening O2 is transferred into the second mask layer 30b, the first mask layer 30a, and the dielectric layer 20b is non-uniform. As a result, the portion of the conductive plug pattern 40b inside the conductive pad pattern 40a is etched deeper, while the portion of the conductive plug pattern 40b outside the conductive pad pattern 40a is etched shallower. Specifically, the bottom of the conductive plug pattern 40b within the conductive pad pattern 40a is the dielectric layer 20b, whereas the bottom of the conductive plug pattern 40b outside the conductive pad pattern 40a is the second mask layer 30b. At this point, the conductive pad pattern 40a and the conductive plug pattern 40b together form a conductive element pattern 40.

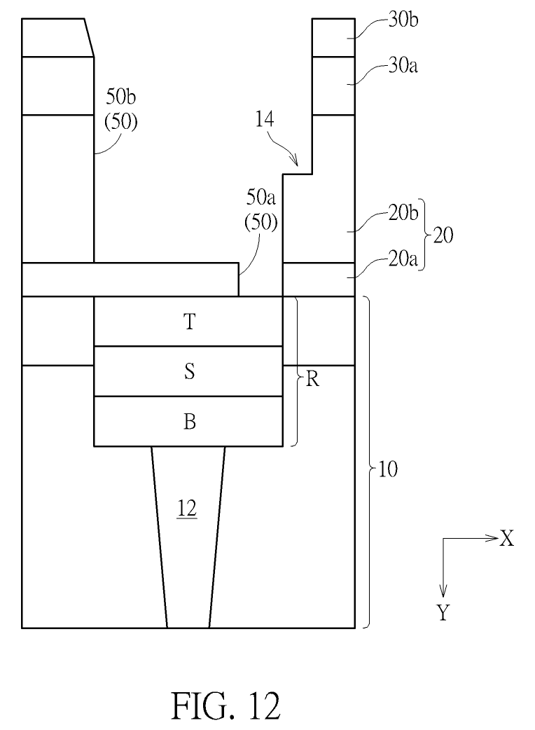

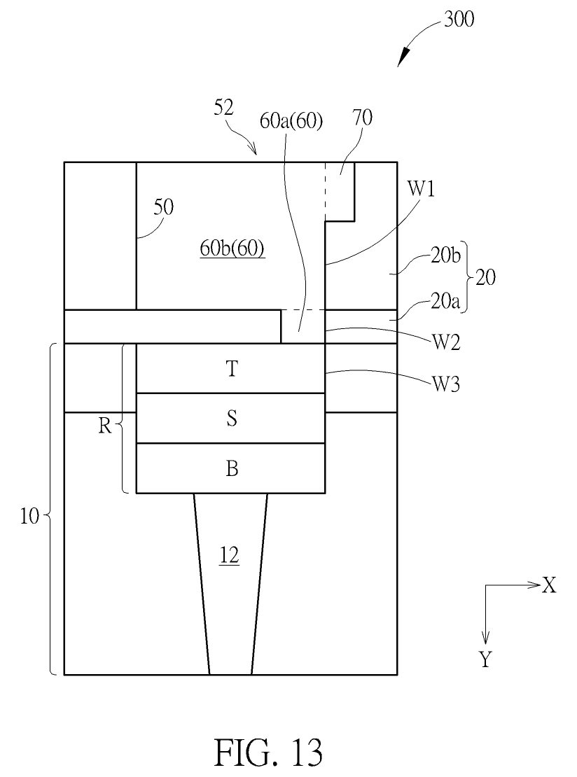

As shown in FIG. 12, using the second mask layer 30b and the first mask layer 30a as a mask, an etching process is performed along the profile of the conductive element pattern 40 to etch the second mask layer 30b, the first mask layer 30a, and the second dielectric layer 20, thereby forming a conductive element trench 50. The top electrode T is exposed through the conductive element trench 50. The conductive element trench 50 includes an upper trench 50b and a lower trench 50a. The width of the upper trench 50b is greater than that of the lower trench 50a. The upper trench 50b is embedded only in the dielectric layer 20b, and the lower trench 50a is embedded only in the dielectric layer 20a. It is noteworthy that a step-like profile 14 is formed on the sidewall of the upper trench 50b. The sidewall of the lower trench 50a is aligned with the sidewall of the RRAM R. As shown in FIG. 13, a metal layer 52 is formed to fill the conductive element trench 50, thereby forming a conductive element 60. At this point, an RRAM structure 300 of the third preferred embodiment of the present invention is completed.

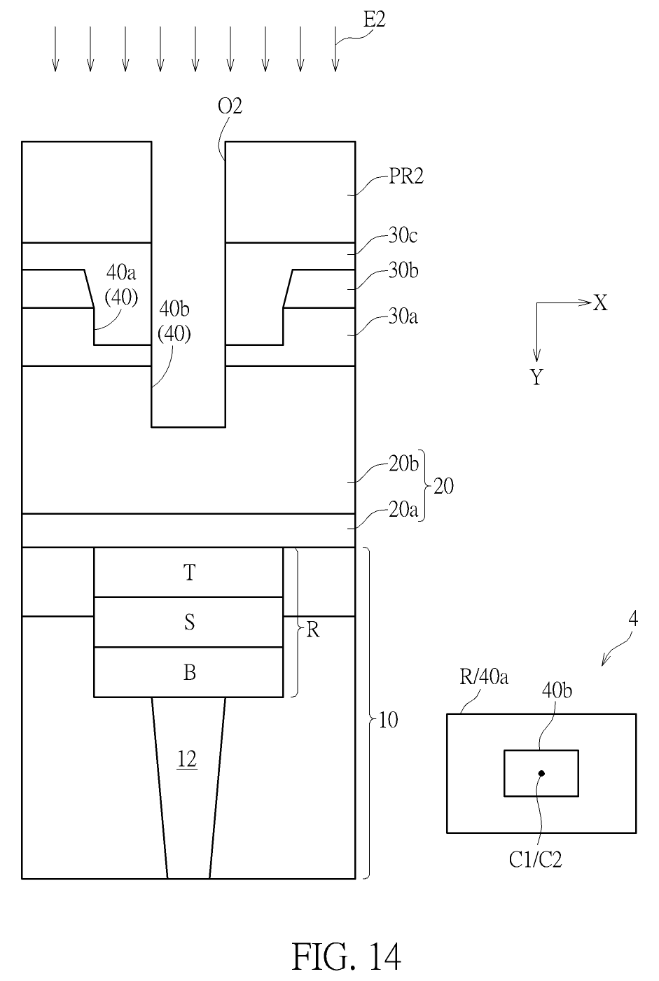

FIGS. 14-16 illustrate a fabricating method of an RRAM structure according to a fourth preferred embodiment of the present invention. Elements having the same functions and positions as those in the third preferred embodiment are designated by the same reference numerals.

The difference between the fourth and the third preferred embodiments lies in the following: in the fourth preferred embodiment, the conductive plug pattern 40b is located at the center of the conductive pad pattern 40a, and does not extend beyond the boundary of the conductive pad pattern 40a. All other process steps are identical to those of the third preferred embodiment. Referring to FIG. 14, following the process of FIG. 10, a third mask layer 30c is formed to cover the second mask layer 30b and fill the conductive pad pattern 40a. Subsequently, a photoresist PR2 is formed on the third mask layer 30c. Then, a second exposure E2 of the double exposure process is carried out to form an opening O2 in the photoresist PR2. The opening O2 defines the location for forming a conductive plug pattern in a subsequent step. Next, using photoresist PR2 as a mask, the third mask layer 30c and the dielectric layer 20b of the second dielectric layer 20 are etched to form the conductive plug pattern 40b within the conductive pad pattern 40a. In this fourth preferred embodiment, during the etching of the third mask layer 30c, the first mask layer 30a, and the dielectric layer 20b to form the conductive plug pattern 40b, the second mask layer 30b is not etched. As viewed along the first direction Y, as shown in a top view 4, the conductive plug pattern 40b is centered within the conductive pad pattern 40a. Specifically, the center C2 of the conductive plug pattern 40b overlaps with the center C1 of the conductive pad pattern 40a. The area of the conductive plug pattern 40b is smaller than that of the conductive pad pattern 40a. Additionally, as seen in a sectional view, the width of the conductive plug pattern 40b is smaller than the width of the conductive pad pattern 40a. At this point, the conductive pad pattern 40a and the conductive plug pattern 40b together form a conductive element pattern 40.

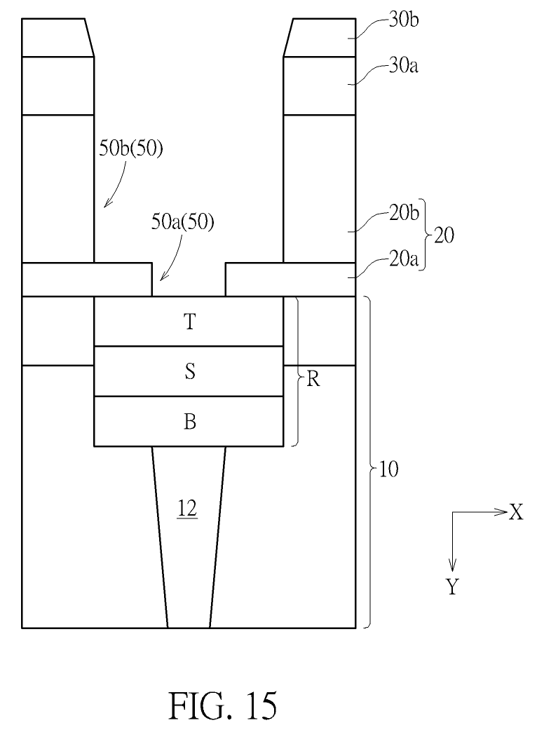

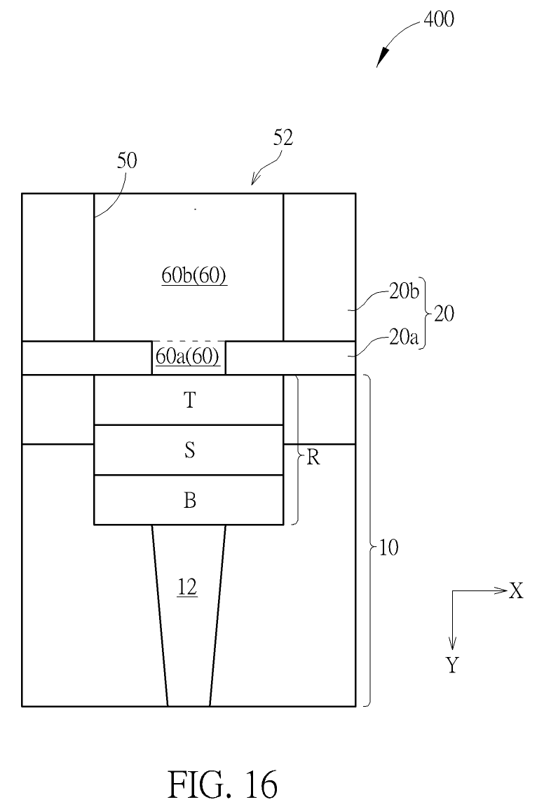

As shown in FIG. 15, using the second mask layer 30b and the first mask layer 30a as a mask, an etching process is carried out along the profile of the conductive element pattern 40 to etch the first mask layer 30a and the second dielectric layer 20, thereby forming a conductive element trench 50. The conductive element trench 50 includes an upper trench 50b and a lower trench 50a. The upper trench 50b is embedded only in the dielectric layer 20b, and the lower trench 50a is embedded only in the dielectric layer 20a. The top electrode T is exposed through the conductive element trench 50. As shown in FIG. 16, a metal layer 52 is formed to fill the conductive element trench 50, thereby forming a conductive element 60. At this point, the fabrication of an RRAM structure 400 according to the fourth preferred embodiment of the present invention is completed.

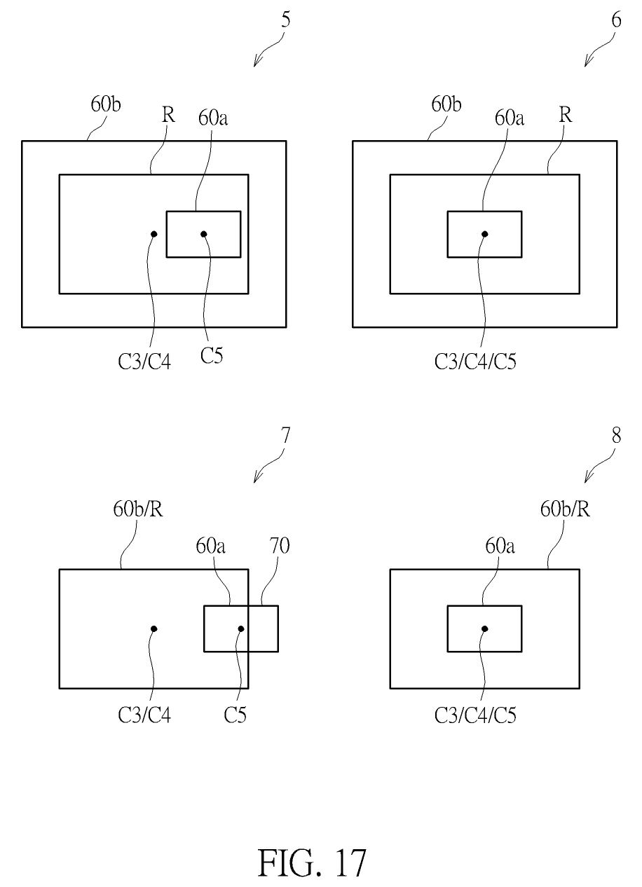

FIG. 5 illustrates an RRAM structure according to a first preferred embodiment of the present invention. FIG. 8 illustrates an RRAM structure according to a second preferred embodiment of the present invention. FIG. 13 illustrates an RRAM structure according to a third preferred embodiment of the present invention. FIG. 16 illustrates an RRAM structure according to a fourth preferred embodiment of the present invention. FIG. 17 is a top view of a conductive element and an RRAM structure according to the first through fourth preferred embodiments of the present invention. In FIGS. 8, 13, 16, and 17, elements having the same functions and positions as those in FIG. 5 are designated by the same reference numerals.

Referring to FIGS. 5 and 17, an RRAM structure 100 fabricated according to the first preferred embodiment of the present invention includes a first dielectric layer 10 and a second dielectric layer 20 formed to cover the first dielectric layer 10. The second dielectric layer 20 includes a dielectric layer 20a and a dielectric layer 20b, wherein the dielectric layer 20b is positioned on the dielectric layer 20a. The dielectric layer 20a and the dielectric layer 20b respectively include an insulating material, such as silicon oxide, silicon nitride, or silicon oxynitride. Preferably, the dielectric layer 20b is made of silicon oxide, and the dielectric layer 20a is made of silicon nitride. The dielectric layer 20a and the dielectric layer 20b must be composed of different materials. Preferably, the first dielectric layer 10 is also made of silicon oxide.

An RRAM R is embedded in the first dielectric layer 10. The RRAM R includes a bottom electrode B, a resistive switching layer S, and a top electrode T, sequentially stacked from bottom to top. A conductive element 60 is embedded in the second dielectric layer 20. The conductive element 60 includes a conductive plug 60a and a conductive pad 60b. The conductive element 60 is formed integrally. For clarity in illustration, the conductive plug 60a and the conductive pad 60b are delineated by dashed lines. The conductive pad 60b refers to the portion of the conductive element 60 embedded in the dielectric layer 20b, and the conductive plug 60a refers to the portion of the conductive element 60 embedded in the dielectric layer 20a. The conductive plug 60a contacts the top electrode T. The conductive pad 60b contacts the conductive plug 60a and is located on the conductive plug 60a. A first direction Y is defined as the direction from the top electrode T toward the bottom electrode B. As shown in a top view 5 of FIG. 17, when viewed along the first direction Y, the conductive plug 60a is laterally offset from the center C3 of the conductive pad 60b and also laterally offset from the center C4 of the RRAM R. Specifically, the center C5 of the conductive plug 60a is laterally offset from both the center C3 of the conductive pad 60b and the center C4 of the RRAM R. When the conductive pad 60b, the RRAM R, and the conductive plug 60a are all rectangular in shape, the center C3 of the conductive pad 60b is defined as the intersection point of the diagonals of the conductive pad 60b, the center C4 of the RRAM R is defined as the intersection point of the diagonals of the RRAM R, and the center C5 of the conductive plug 60a is defined as the intersection point of the diagonals of the conductive plug 60a. The conductive plug 60a is entirely located within the boundary of the conductive pad 60b. In addition, the area of the conductive pad 60b is greater than the area of the conductive plug 60a, and also greater than the area of the RRAM R. A second direction X is defined as a direction parallel to the top surface of the first dielectric layer 10. Along the second direction X, the width of the conductive pad 60b is greater than the width of the top electrode T and also greater than the width of the conductive plug 60a. Furthermore, along the first direction Y, the thickness of the conductive pad 60b is 5 to 10 times the thickness of the conductive plug 60a. Moreover, an entirety of the conductive pad 60b does not contact the RRAM R.

The top electrode T and the bottom electrode B may respectively include titanium nitride, tantalum nitride, tungsten, copper, aluminum, gold, silver, platinum, titanium, or other conductive materials. The resistive switching layer S may include aluminum oxide, tantalum oxide, titanium oxide, hafnium oxide, or other metal oxides. The materials of the conductive pad 60b and the conductive plug 60a may respectively include copper, aluminum, nickel, tungsten, titanium, tantalum, or other conductive materials.

Please refer to both FIGS. 8 and 17. The difference between the RRAM structure 200 of the second preferred embodiment and the RRAM structure 100 of the first preferred embodiment is that, as shown in a top view 6 in FIG. 17, along the first direction Y, the conductive plug 60a is located at the center C3 of the conductive pad 60b and also at the center C4 of the RRAM. The center C5 of the conductive plug 60a, the center C3 of the conductive pad 60b, and the center C4 of the RRAM R overlap with each other. All other elements are the same as those in the first preferred embodiment and will not be repeated here.

Please refer to FIGS. 13 and 17. The difference between the third preferred embodiment of the RRAM structure 300 and the first preferred embodiment of the RRAM structure 100 is that along the second direction X, the width of the conductive pad 60b is not greater than the width of the top electrode T. According to the preferred embodiment of the present invention, the width of the conductive pad 60b is equal to the width of the top electrode T. Additionally, the conductive pad 60b includes a first sidewall W1, the conductive plug 60a includes a second sidewall W2, and the RRAM structure includes a third sidewall W3. The first sidewall W1, the second sidewall W2, and the third sidewall W3 align with each other. Furthermore, a protrusion 70 extends from the first sidewall W1 along the second direction X. The top surface of the protrusion 70 is aligned with the top surface of the conductive pad 60b. The conductive element 60, which includes the conductive plug 60a, the conductive pad 60b, and the protrusion 70, is monolithic. For clarity, the conductive plug 60a, the conductive pad 60b, and protrusion 70 are separated by dashed lines. As shown in FIG. 13 and a top view 7 of FIG. 17, along the first direction Y, the area of the conductive pad 60b coincides with the area of the RRAM structure, while the protrusion 70 is outside the boundary of the conductive pad 60b. Furthermore, the center C5 of the conductive plug 60a not only offset from the center C3 of the conductive pad 60b but also, along the first direction Y, the conductive plug 60a and the protrusion 70 can form a complete rectangle. Other elements are the same as in the first preferred embodiment and will not be repeated here.

Please refer to FIGS. 16 and 17. The difference between the RRAM structure 400 of the fourth preferred embodiment of and the RRAM structure 100of the first preferred embodiment is as follows: As shown in a top view 8 of FIG. 17, when viewed along the first direction Y, the conductive plug 60a is located at the center C3 of the conductive pad 60b and also at the center C4 of the RRAM R. The center C5 of the conductive plug 60a, the center C3 of the conductive pad 60b, and the center C4 of the RRAM R overlap with each other. The area of the conductive pad 60b coincides with the area of the RRAM R. All other elements are the same as those in the first preferred embodiment and will not be repeated here.

The fabrication process of the conductive element in the present invention utilizes the overlay of a conductive pad pattern and a conductive plug pattern to define a conductive element pattern on a mask. Using the conductive element pattern as a template, the second dielectric layer is etched and subsequently filled with a metal layer to form the conductive element. If the conductive element is formed using only the conductive pad pattern as a template, there is a risk of incomplete contact or even no contact between the conductive element and the top electrode. However, by overlaying the conductive plug pattern with the conductive pad pattern, the resulting conductive element formed at the overlapping region ensures complete contact with the top electrode.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A resistive random access memory (RRAM) structure, comprising:
a first dielectric layer;
a second dielectric layer covering the first dielectric layer;
an RRAM embedded in the first dielectric layer, wherein the RRAM comprises a bottom electrode, a resistive switching layer, and a top electrode sequentially stacked from bottom to top;
a conductive element embedded in the second dielectric layer, wherein the conductive element comprises:
a conductive plug in contact with the top electrode;
a conductive pad in contact with the conductive plug and disposed on the conductive plug; and
a first direction defined from the top electrode toward the bottom electrode, wherein when viewed along the first direction, the conductive plug is offset from a center of the conductive pad.

2. The RRAM structure of claim 1, wherein a second direction is defined as being parallel to a top surface of the first dielectric layer, and along the second direction, a width of the conductive pad is greater than a width of the top electrode.

3. The RRAM structure of claim 1, wherein a second direction is defined as being parallel to a top surface of the first dielectric layer, and along the second direction, a width of the conductive pad is not greater than a width of the top electrode.

4. The RRAM structure of claim 3, wherein the conductive pad comprises a first sidewall, the conductive plug comprises a second sidewall, and the RRAM comprises a third sidewall, and wherein the first sidewall, the second sidewall, and the third sidewall are aligned with each other.

5. The RRAM structure of claim 4, further comprising a protrusion, wherein the protrusion protrudes from the first sidewall along the second direction, and a top surface of the protrusion is aligned with a top surface of the conductive pad.

6. The RRAM structure of claim 1, wherein a second direction is defined as being parallel to a top surface of the first dielectric layer, and along the second direction, a width of the conductive pad is greater than a width of the conductive plug.

7. The RRAM structure of claim 1, wherein along the first direction, a thickness of the conductive pad is 5 to 10 times a thickness of the conductive plug.

8. The RRAM structure of claim 1, wherein an entirety of the conductive pad does not contact the RRAM.

9. A fabricating method of a resistive random access memory (RRAM) structure, comprising:
providing a first dielectric layer, a second dielectric layer, and an RRAM, wherein the second dielectric layer covers the first dielectric layer, and the RRAM is embedded in the first dielectric layer, wherein the RRAM comprises a bottom electrode, a resistive switching layer, and a top electrode sequentially stacked from bottom to top;
forming a first mask layer and a second mask layer covering the second dielectric layer from bottom to top;
etching the second mask layer and the first mask layer to form a conductive pad pattern in the second mask layer and the first mask layer;
forming a third mask layer covering the second mask layer and filling the conductive pad pattern;
etching the third mask layer, the first mask layer, and the second dielectric layer to form a conductive plug pattern in the conductive pad pattern, wherein a first direction is defined from the top electrode toward the bottom electrode and when viewed along the first direction, the conductive plug pattern is offset from a center of the conductive pad pattern;
removing the third mask layer entirely after forming the conductive plug pattern;
using the second mask layer and the first mask layer as a mask, etching the second dielectric layer to form a conductive element trench, and exposing the top electrode from the conductive element trench; and
forming a metal layer to fill the conductive element trench to form a conductive element.

10. The fabricating method of the RRAM structure of claim 9, wherein a second direction is defined as being parallel to a top surface of the first dielectric layer, and along the second direction, a width of the conductive pad pattern is greater than a width of the top electrode.

11. The fabricating method of the RRAM structure of claim 10, wherein when viewed along the first direction, the conductive plug pattern is entirely within the conductive pad pattern.

12. The fabricating method of the RRAM structure of claim 10, wherein while etching the third mask layer, the first mask layer, and the second dielectric layer to form the conductive plug pattern, the second mask layer is not etched.

13. The fabricating method of the RRAM structure of claim 9, wherein while etching the third mask layer, the first mask layer, and the second dielectric layer to form the conductive plug pattern, the second dielectric layer is not etched through.

14. The fabricating method of the RRAM structure of claim 9, wherein while etching the second mask layer and the first mask layer to form the conductive pad pattern, the second mask layer is not etched through.

15. The fabricating method of the RRAM structure of claim 9, wherein a second direction is defined as being parallel to a top surface of the first dielectric layer, and along the second direction, a width of the conductive pad pattern is not greater than a width of the top electrode.

16. The fabricating method of the RRAM structure of claim 15, wherein when viewed along the first direction, part of the conductive plug pattern is outside of the conductive pad pattern.

17. The fabricating method of the RRAM structure of claim 16, wherein while etching the third mask layer, the first mask layer and the second dielectric layer to form the conductive plug pattern, the second mask layer which is outside of the conductive pad pattern is etched.

18. The fabricating method of the RRAM structure of claim 15, wherein the conductive element comprises:
a conductive plug, the conductive plug contacting the top electrode; and
a conductive pad, the conductive pad contacting the conductive plug and positioned on the conductive plug, wherein the conductive pad comprises a first sidewall, the conductive plug comprises a second sidewall, and the RRAM comprises a third sidewall, the first sidewall, the second sidewall, and the third sidewall are aligned with each other.

19. The fabricating method of the RRAM structure of claim 18, wherein the conductive element further comprises a protrusion, the protrusion protrudes from the first sidewall along the second direction, and a top surface of the protrusion is aligned with a top surface of the conductive pad.
